(19) United States
(12) Patent Application Publication
(10) Pub. No.: US 2014/0209928 A1
(43) Pub. Date: Jul. 31, 2014

(54) LIGHT SOURCE ASSEMBLY AND A PROCESS FOR PRODUCING A LIGHT SOURCE ASSEMBLY

(71) Applicant: The Silanna Group Pty Ltd, Eight Mile Plains, Queensland (AU)

(72) Inventors: Annette Teng, Eight Mile Plains (AU); Steven Grant Duvall, Milsons Point (AU)

(21) Appl. No.: 14/346,717

(22) PCT Filed: Sep. 21, 2012
(86) PCT No.: PCT/AU2012/001143

§ 371 Date: Mar. 22, 2014

Related U.S. Application Data
(60) Provisional application No. 61/538,105, filed on Sep. 22, 2011.

(51) Int. Cl. H01L 25/075; H01L 25/16; H01L 25/00; H01L 25/18

(52) U.S. Cl. CPC H01L 25/0753; H01L 25/18; H01L 25/167; H01L 25/50
USPC 257/82; 257/88; 438/28

(57) ABSTRACT

A light source assembly, including one or more light emitting diodes disposed within a hermetically sealed enclosure, wherein the light emitting diodes are in the form of one or more unpackaged planar semiconductor dies mounted on an inner surface of a wall of the enclosure, wherein the wall of the enclosure includes electrically conductive tracks that connect electrical contacts of the unpackaged planar semiconductor dies to corresponding electrical contacts external of the sealed enclosure.

### TECHNICAL FIELD

The present invention relates to a light source assembly and a process for producing a light source assembly, and in particular to light source assemblies in which at least one semiconductor LED die is hermetically sealed within a single enclosure.

### BACKGROUND

Light emitting diodes are becoming increasingly popular as light sources for general and specialist lighting applications due to their high efficiencies, long lifetimes, and relatively low toxicity compared to fluorescent lights. However, currently available LED-based light sources suffer from a number of difficulties, in particular their relatively high manufacturing costs. These high costs arise in part from the complexity of LED packaging processes, whereby a large number of manufacturing steps are used to assemble numerous sub-mounts and other components (and using disparate materials such as epoxy and solder) before the LED chip or die to be packaged is even mounted.

In addition, some specialist lighting applications have their own difficulties. For example, mercury vapour lamps are used as high intensity UV light sources for curing and sterilisation in various industries, but mercury vapour lamps have relatively short lifetimes, and bulb changes are extremely expensive due to the associated downtime. In view of their long lifetimes, it would be desirable to replace the mercury vapour lamps with UV-emitting LED light sources, but currently available UV light sources using LEDs do not have sufficient brightness.

It is desired to provide a light source assembly and a process for producing a light source assembly that alleviate one or more difficulties of the prior art, or that at least provide a useful alternative.

### SUMMARY

In accordance with some embodiments of the present invention, there is provided a light source assembly, including one or more light emitting diodes disposed within a hermetically sealed enclosure, wherein the light emitting diodes are in the form of one or more unpackaged planar semiconductor dies mounted on an inner surface of a wall of the enclosure, wherein the wall of the enclosure includes electrically conductive tracks that connect electrical contacts of the unpackaged planar semiconductor dies to corresponding electrical contacts external of the sealed enclosure.

In some embodiments, the electrically conductive tracks are disposed within corresponding recesses in the wall of the enclosure. In some embodiments, the electrically conductive tracks are formed from a conductive paste.

In some embodiments, the electrical contacts of each unpackaged planar semiconductor die include bumps, and the recesses in the wall of the enclosure include bump recesses in which the bumps of the unpackaged planar semiconductor dies are disposed and which act to locate the unpackaged planar semiconductor dies.

In some embodiments, the inner surface of the wall of the enclosure is planar, and each unpackaged planar semiconductor die is mounted substantially flush against the inner planar surface of the wall of the enclosure. In some embodiments, the inner surface of the wall of the enclosure is a curved surface.

In some embodiments, each unpackaged planar semiconductor die is configured to selectively emit UV radiation.

In some embodiments, the one or more unpackaged planar semiconductor dies are a plurality of unpackaged planar semiconductor dies.

In some embodiments, the plurality of unpackaged planar semiconductor dies are arranged as a one-dimensional array. In other embodiments, the plurality of unpackaged planar semiconductor dies are arranged as a two-dimensional array.

In some embodiments, the light source assembly includes one or more sensors mounted within the sealed enclosure. In some embodiments, the one or more sensors include one or more photo detectors to monitor the intensity of light emitted by the light emitting diodes.

In some embodiments, the wall of the enclosure is optically transparent. In some embodiments, the wall is one of a plurality of optically transparent walls of the enclosure.

In some embodiments, each unpackaged planar semiconductor die is mounted to the inner planar surface of the enclosure in a flip chip configuration.

In some embodiments, the light source assembly is substantially in the form of a flat panel.

In some embodiments, a plurality of the light source assemblies are arranged circumferentially about a region and directed radially inwards to said region.

In accordance with some embodiments of the present invention, there is provided a light source assembly, including one or more light emitting diodes disposed within a hermetically sealed enclosure, wherein the light emitting diodes are in the form of one or more unpackaged planar semiconductor dies mounted in respective openings in a wall of the enclosure such that the enclosure is formed in part by the unpackaged planar semiconductor dies, and wherein the wall of the enclosure includes electrically conductive tracks that connect electrical contacts of the unpackaged planar semiconductor dies to corresponding electrical contacts external of the sealed enclosure.

In accordance with some embodiments of the present invention, there is provided a process for producing a light source assembly, including:
forming electrically conductive tracks on a substrate;
mounting one or more light emitting diodes in the form of one or more unpackaged planar semiconductor dies to the substrate such that the electrically conductive tracks are electrically connected to electrical contacts of each unpackaged planar semiconductor die; and
hermetically sealing the unpackaged planar semiconductor dies within an enclosure formed in part by the substrate.

In some embodiments, the substrate is an optically transparent substrate.

In some embodiments, said mounting includes flip-chip mounting the unpackaged planar semiconductor dies to the substrate.

In some embodiments, said mounting includes mounting the unpackaged planar semiconductor dies in respective openings in the substrate such that the enclosure is formed in part by the unpackaged planar semiconductor dies.

In some embodiments, the one or more light emitting diodes are a plurality of light emitting diodes, and the electrical contacts external of the sealed enclosure allow at least one of the light emitting diodes to be controlled independently of at least one other one of the light emitting diodes.

In some embodiments, each of the one or more unpackaged planar semiconductor dies has a light emitting planar surface spaced from a corresponding inner surface of the hermetically sealed enclosure and defining a gap therebetween, and the light source assembly includes a fluid or gel in the gap to assist with cooling the unpackaged planar semiconductor dies and/or to modify the light emission from the light source assembly.

In some embodiments, the fluid or gel includes phosphor and/or diffusing particles to modify the wavelengths and/or directionality of light emission.

### BRIEF DESCRIPTION OF THE DRAWINGS

Some embodiments of the present invention are hereinafter described, by way of example only, with reference to the accompanying drawings, wherein:

FIGS. 1a and 1b are schematic plan views of substrates with recesses for receiving electrically conductive tracks in accordance with respective embodiments of the present invention;

FIGS. 2a and 2b show the substrates of FIGS. 1a and 1b after electrically conductive paste has been dispensed into the recesses in the substrates;

FIGS. 3a and 3b show the substrates of FIGS. 2a and 2b after mounting metal plugs and unpackaged semiconductor LED dies onto the conductive paste;

FIGS. 4a and 4b are schematic cross-sectional side views illustrating the mounting of unpackaged LED dies with different forms of bump contacts into corresponding recesses in the substrate in accordance with respective embodiments of the present invention;

FIG. 5 is a schematic cross-sectional side view of an unpackaged LED die mounted flush with the substrate in accordance with some embodiments of the present invention;

FIGS. 6a and 6b are schematic perspective views of unpackaged LED dies mounted on respective substrates in accordance with respective embodiments of the present invention;

FIGS. 7a and 7b are schematic perspective views of the embodiments of FIGS. 6a and 6b with the addition of reinforcements to strengthen the attachment of the unpackaged LED dies to the substrates;

FIG. 8 is a schematic perspective view of a substrate in accordance with some embodiments of the present invention, including interconnected unpackaged LED dies mounted in different orientations and with sealant dispensed about the periphery of the substrate prior to sealing;

FIGS. 9 and 10 are schematic side views of light source assemblies in accordance with respective embodiments of the present invention, wherein the assemblies are sealed with lids that are lipped and not lipped, respectively;

FIG. 11 is a schematic plan view of a light source assembly containing multiple unpackaged LED dies in a linear or one-dimensional array;

FIG. 12 is a schematic plan view of a light source assembly containing multiple unpackaged LED dies in a two-dimensional array;

FIGS. 13 and 14 are schematic perspective and end views of generally circumferential arrangements of respectively six and twelve planar light source assemblies configured to direct light radially inwards;

FIG. 15 is a schematic plan view of a planar light source assembly containing a two-dimensional array of unpackaged LED dies and a sensor;

FIG. 16 is a schematic end view of an arrangement of four instances of the planar light source assembly of FIG. 15; and

FIG. 17 is a flow diagram of a process for producing a light source assembly in accordance with an embodiment of the present invention.

### DETAILED DESCRIPTION

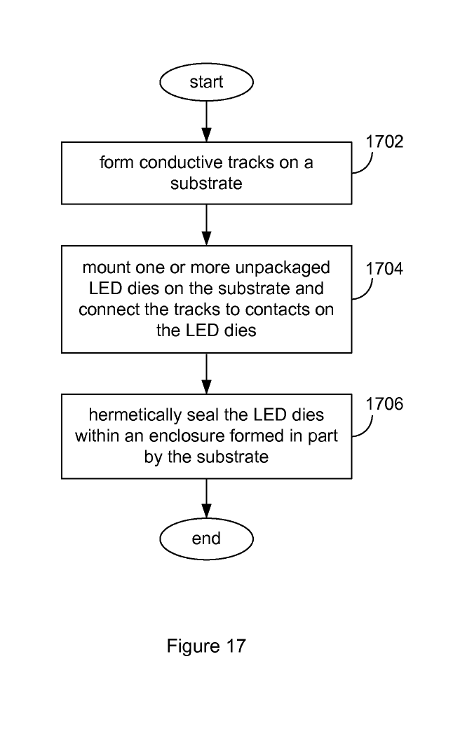

As shown in the flow diagram of FIG. 17, a process for producing a light source assembly begins at step 1702 by forming electrically conductive tracks on a substrate. In the described embodiments, the substrate is selected as one that is made of a material that is substantially transparent to the desired range of wavelengths of radiation emitted from the light source assembly, although this need not be the case in other embodiments, as described further below.

In the described embodiments, the light source assembly is configured to predominantly emit UV radiation for sterilisation and curing purposes, and consequently the substrate is selected to be substantially transparent to UV radiation, and ‘ultraviolet C’ or UVC radiation (i.e., wavelengths in the range of about 100-280 nm) in particular for germicidal applications. However, other embodiments include light source assemblies configured for other applications, including general lighting applications, and can therefore have wavelength ranges anywhere across the entire spectrum from 200 to 2000 nanometers.

In the described embodiments, the UV transparent substrate is further selected to be transparent to wavelengths in the visible region, thereby facilitating unassisted human inspection of the inner components of the light source assembly, although this need not be the case in other embodiments.

In some embodiments, the substrate is a sapphire substrate. In other embodiments, the substrate is calcium fluoride, which has better transparency in the shorter wavelength regions of the UVC spectrum. In yet other embodiments, the substrate is magnesium fluoride. Other such substrate materials will be apparent to those skilled in the art. However, in the embodiments described further below, the substrate is a glass plate. Glass formulations with very specific transparency ranges are commercially available and can be selected for application to a particular wavelength or range of wavelengths. In particular, the UV region with wavelengths down to 200 nanometers requires glass formulations transparent in this range of the spectrum, such as Schott Glass 8337B or Schott Glass 8405. In some embodiments, the glass plate is polished; in other embodiments, at least part of the glass substrate is unpolished or even roughened to modify light transmission through the glass substrate.

In the described embodiments, the conductive tracks are formed in recesses in the substrate, but this need not be the case in other embodiments. In the described embodiments, the recesses are formed by laser ablation, although alternative methods such as selected area etching, scribing, stamping or embossing can be used in other embodiments. In some embodiments, the recesses are formed by casting the glass substrate in a mould having corresponding features that define the recesses. In some embodiments, the laser, etching, or scribing is used to roughen the surface of the substrates, rather than to form recesses in it.

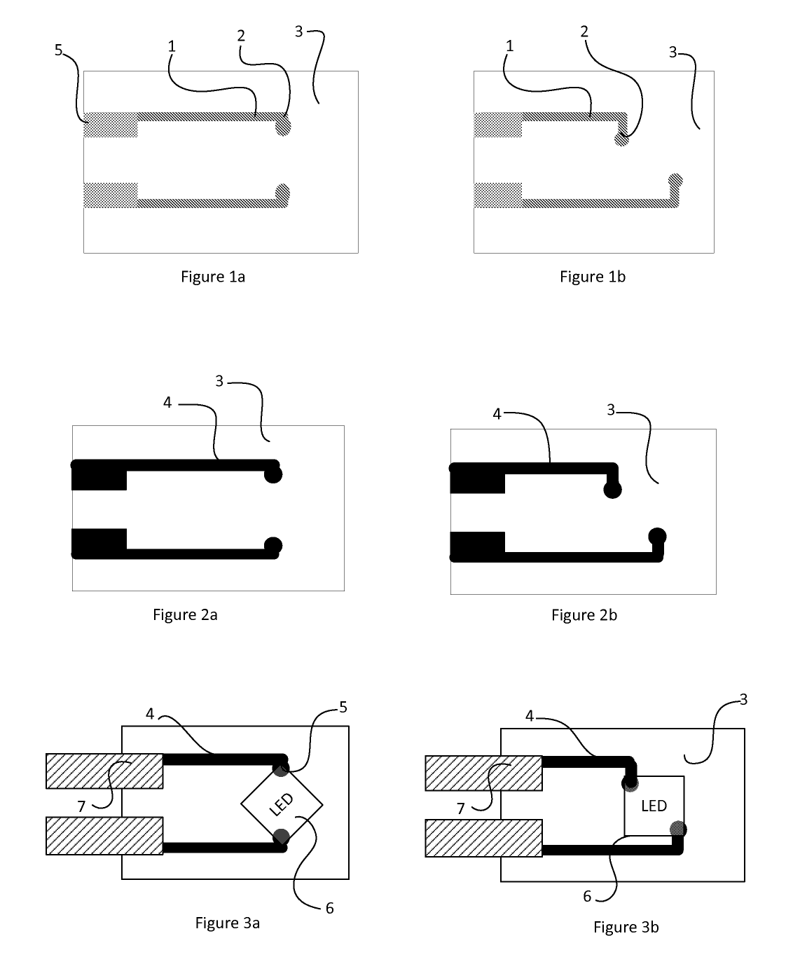

FIG. 1a is a schematic plan view of a substrate 3 with a pattern of recesses and/or trenches 1, 2 (or roughened regions in other embodiments, as described further below) in which the electrically conductive tracks will be formed. FIG. 1b is the same as FIG. 1a, but shows a slightly different arrangement of the recesses or trenches 1. Although the substrate 3 is a planar substrate in the described embodiments, the substrate may be curved in other embodiments.

The recesses 1 are formed by directing a pulsed UV laser beam generated by a CO₂ laser along the desired path or pattern of the recesses 1, 2. The laser beam ablates the surface of the glass substrate 3 to form shallow recesses and/or trenches 1, 2 that do not extend through the entire thickness of the substrate 3. Using the CO₂ laser, the width and depth of the recesses 1, 2 can be selected to be around 15 μm to 50 μm. However, for applications in which increased conduction of heat is desired, the widths and depths of the recesses/trenches 1, 2 can be increased by repeatedly directing the laser beam over the same regions of the substrate 3.

In alternative embodiments, the recesses/trenches 1, 2 can be created by using acid etchants and masked patterns on the surface of the substrate 3. This can be achieved as a batch process on a large piece of glass or a glass wafer and later singulated into individual substrates such as those shown in FIGS. 1a and 1b. This alternative method requires coating and lithography and may be better suited for higher resolution and finer pitched recesses 1, 2.

As can be seen in FIG. 1a, in the described embodiments one end of each recess or trench 1 is terminated with a generally part-spherical well or pit 2 having a depth and diameter of about 75-100 μm. These features 2 are to accommodate or receive corresponding bump contacts of unpackaged or bare semiconductor dies in which light emitting diodes (LEDs) have been formed. For convenience of reference, such dies are referred to herein as “LED dies”. Like the elongate trenches 1, the wells or pits 2 are also created by laser pulses from the CO₂ laser. At the other end of each recess or trench 1, a wider and deeper recessed region 5 is formed to accommodate relatively large electrical contact pins, as described further below.

Once the recesses (or roughened regions) 1, 2 have been formed, electrically conductive paste 4, 5 is dispensed into those recesses (or onto roughened regions) 1 and (where applicable) wells 2. If the width of the recesses or wells 1, 2 is less than about 75 μm, this can be achieved using a micro-nozzle attached to a dispenser machine such as those made by EFD Nordson or Asymtek, for example. Alternatively, a patterned stencil having openings corresponding to the desired locations of conductive paste can be used. The conductive paste is forced into the openings of the stencil with a blade moving over the surface at an angle. The bump receiving wells 2 are only partially filled with paste so that the LED die bumps can be accommodated without forcing excess conductive paste out of the wells 2 and potentially forming an electrical short circuit.

For applications involving high temperature and/or intense UV exposure, the conductive paste can be a silver glass such as those widely used as die attach adhesives for ceramic packaging; for example, those described in U.S. Pat. No. 4,636,254 (Husson) or in U.S. Pat. Nos. 4,401,767 and 5,334,558 (both to Dietz). The use of silver glass can be advantageous, not only because it can withstand high temperatures up to 400° C., but also because it has strong adhesion to the glass substrate and a relatively low thermal expansion coefficient. Additionally, silver glass is not polymer-based and can withstand UV radiation without degradation, thereby extending the lifetime of the light assemblies described herein relative to light assemblies with polymer encapsulation. The light assemblies described herein using silver glass can withstand operating temperatures above 200° C., whereas solder connections are at risk of failing at operating temperatures of about 150° C. and higher. For example, LEDs typically operate at temperatures around 125° C., but when used in environments with high ambient temperatures (e.g., in a hot car), can operate at temperatures up to about 150° C. The resulting thermal cycling up to such high temperatures can cause the solder connections of conventionally packaged LEDs to fatigue and eventually fail.

By dispensing the conductive paste 4 into recesses (or roughened surface regions in some other embodiments) 1, the conductive paste 4 remains confined inside the recesses (or on the roughened surface regions) 1 and does not spread over the surface of the substrate 3.

As an alternative to silver glass, a conductive solder alloy paste can be used. The adhesion of such pastes to the glass substrate can be substantially enhanced by pre-deposition of adhesion metals, such as Nickel (Ni) over Titanium tungsten (TiW). Such pre-metallization can be achieved by sputtering or evaporating the adhesion metal layers (e.g., Cr, TiW, Ni) onto the masked surface of the glass 3. Then the solder can be deposited over the adhesion metal(s), either by stencil or by local dispensing, to create the desired arrangement of conductive pathways. These are then reflowed to melt the solder into the adhesion metal layer, thereby creating a strong metallurgical bond. In some embodiments, common Pb—Sn or Sn—Ag—Cu solder pastes are used because they are relatively low in cost and are reflowable at relatively low temperatures (below 260° C.). However, for applications requiring operation at high temperatures above 200° C., higher melt solders are used, such as 95% Pb 5% Sn or 80% Au 20% Sn alloys with melting points of 310° C. and 280° C., respectively. AuSn alloys are often used because they have a lower coefficient of thermal expansion and are Pb-free.

A third alternative family of materials for making the conductive tracks on the substrate 3 is the family of epoxy-based silver pastes. These pastes are electrically and thermally conductive, are easily dispensed into the recesses 1 and wells 2 using a small dispensing nozzle, and have very good adhesion to the glass substrate 3. They are dispensed as a soft paste and are cured to form solid conductors at relatively low temperatures around 150° C., which is 50% lower than the cure temperature of the silver glasses described above. One example of such an epoxy-based silver paste is Henkel Ablebond 84-1LMI, where the curing is performed at 150° C. for 60 minutes. Silver epoxy is typically used in non-UV and lower power light source assemblies where epoxies are used as the sealant and/or adhesive. Silver epoxy retains its conductive properties when briefly exposed to high seal temperatures in the subsequent process.

All three families of thick film conductive paste materials can be dispensed by nozzle or by other means such as by a blade (e.g., scalpel) stencilling method similar to screen printing with a patterned cutout or stencil made of a sheet of metal. In these latter methods, the stencils are drilled with holes that match the footprints of the conductors. While the stencil is carefully aligned and pressed over the substrate, the conductive paste is pushed inside the recesses 1 and wells 2 with a blade to create continuous conducting tracks. The stencil sheet is removed while the paste remains on the substrate to be permanently melted on. Any residual paste can be removed from the glass substrate 3 by the blade and/or by wiping with a lint-free cloth or tissue such as Terra Universal™ clean wipes.

A larger volume of the conductive paste is needed in the deeper recessed regions 5 for the electrically conductive pins, plugs, contacts or terminals 7 that are placed over the conductive paste in these regions 5 so that they protrude from the edge of the substrate 3, as shown in FIGS. 3a and 3b. Metallic pins, plugs, contacts or terminals (generally referred to herein as “terminals” for convenience) of various shapes can be used and are placed in the deeper recessed regions 5 while the conductive paste is still uncured to improve the Ohmic contact after curing. The physical widths of these terminals 7 are typically about 100× larger than the widths of the conductive tracks 4 to facilitate the making of external connections to the light source assemblies. The terminals 7 are held in place by subsequent solidification of the surrounding seal glass, which forms a hermetic glass seal with the glass substrate 3, as described below. In other embodiments, the terminals 7 have a head or “T” shaped or similar feature to physically anchor the terminals 7 during glass reflow. In some embodiments, the end result is a pair of terminals 7 protruding from a hermetically sealed enclosure and configured so that the light source assembly can be inserted into a standard power socket/light fitting/mount.

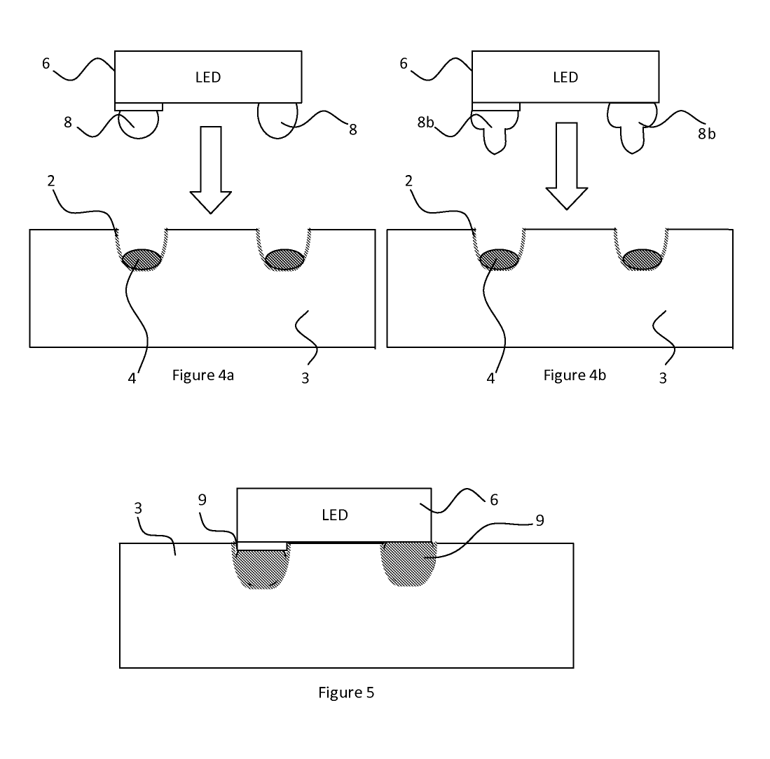

As known by those skilled in the art, semiconductor LED dies are fabricated either with or without bump contacts. Dies without bumps are intended for wirebonding, and are usually configured to emit light from their top (i.e., ‘front’) surface. Conversely, dies with bumps or pillars are intended for flip chip packages with back side light emission. Flip chip dies are commonly ‘pre-bumped’ with balls or pillars composed of tin or copper based alloys. Such solder balls are subsequently reflowed onto the semiconductor die, creating a rounded bump surface for further interconnection by flip chip mounting, as shown in FIG. 4a. Alternatively, unbumped dies with bare aluminium contact pads can be bumped by gold stud bumping using a wire bonder to form protruding stud bumps 8b for flip chipping, as shown in FIG. 4b. The diameter and height of the stud bumps 8b are each about 70 μm and each stud bump 8b is tapered at its end. However, these dimensions can be decreased or increased, depending on the diameter of the gold wire that is used. Typically, a 25 μm gold wire is used to create a 70 μm bump. At step 1704, a semiconductor LED die or chip 6 with bump contacts 8 is picked up by a vacuum pick up tool from its rear surface, and cameras are used to align the bumps 8 with the matching wells 2 on the glass substrate 3, as shown in FIGS. 4a and 4b. The vacuum tool lowers the semiconductor LED die 6 to allow its solder bumps 8 or gold stud bumps 8b to be fully embedded into the wells 2 filled with silver glass paste 4. The amount of conductive paste 4 in the wells is selected to 75-90% fill the wells 2 in order to prevent any overflow of conductive paste 4 onto light emitting surfaces.

During placement in the wells 2, a light pressure is applied to the rear surface of the semiconductor LED die 6 to ensure that the die 6 is substantially parallel to the surface of the substrate 3 and to reduce any standoff of the semiconductor LED die 6 from the glass substrate 3. Thus in some embodiments the planar surface of the LED die 6 is in direct contact with the planar glass substrate 3, whereas in other embodiments there is a small gap therebetween (including embodiments where the substrate is curved). Both the gold bumps 8 and the conductive paste 4 are soft and deformable. Flip-chip bonders control forces in the gram per bump range to facilitate settling the semiconductor LED die 6 into the conductive paste 4 in the well 2. It is usually the case that the light emitting surface of the semiconductor LED die 6 is flush with the pre-polished surface of the glass substrate 3 to improve light transmission, as shown in FIG. 5.

Irrespective of which type of material is used to form the conductive tracks, a thermal treatment is used to solidify the paste (if used) and to firmly cement the LED bumps 8 to the conductive material 5 within the well 2. Silver glass paste is cured at temperatures of 300-440° C., whereas silver glass is cured at lower temperatures, typically about 150° C. Solder paste is not cured, but is reflowed at a temperature of about 220-260° C. so that inter-metallics are formed with the underlying adhesion metallization inside the recesses 1 and wells 2.

The flip-chip mounting step 1704 brings the solder bump 8 inside the well in full contact with the solder paste 4. During reflow, the solder bump 8 melts and contacts the solder paste to form a metallurgical connection 9 with low resistivity. Similarly, a gold stud bump 8b reflows and bonds to the solder paste, forming a metallurgical connection 9 to the semiconductor LED die 6.

Both solder bumps 8 and gold stud bumps 8b can form mechanical bonds to the conductive paste 4 (either silver glass or silver epoxy) with good Ohmic contact. Roughening of the walls of the pits or wells 2 by laser can promote increased surface area for bump to paste bonding. Microscopic perforations in the gold bump 8b or copper pillar by glass debris and roughened walls further enhance the interlocking inside the pits 2.

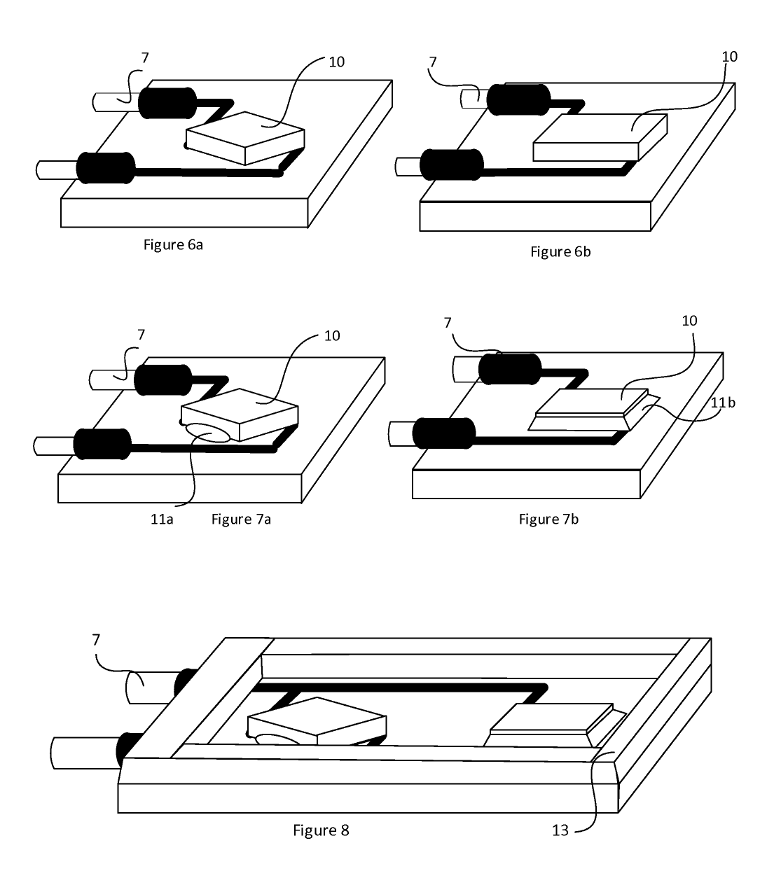

FIGS. 6a and 6b are schematic perspective views of the unpackaged LED dies 6 mounted on respective substrates 3 as described above and as shown in plan view in FIGS. 3a and 3b, except that the unpackaged LED die 6 is rotated in FIG. 6a relative to the arrangement in FIG. 3a, and the conductive tracks configured accordingly. The flip-chip mounted unpackaged LED dies 6 are attached to the glass substrate 3 at only two locations (corresponding to the locations of the contact bumps 8 on the dies 6), which might not be strong enough to survive mechanical handling or thermal excursions during the lifetime of the light source assembly in some applications. To strengthen the bonding between the substrate 3 and the LED die 6, adhesive reinforcements 11a, 11b can be dot or linearly dispensed on a single or on multiple sides of the LED dies 6, as shown in FIGS. 7a and 7b, which may form a fillet at the junction between the side of the die 6 and the substrate 3.

This reinforcement material can be a frit glass paste, which may or may not be non-conductive and may or may not be transparent to the light emitted by the LED die 6. One example of a suitable adhesive material is frit glass paste that can be dispensed by nozzle and hardened by thermal curing. However, if frit glass is used, then solders or epoxies with lower melting points cannot be used as the conductive material 4 in the recesses 1 or wells 2. One type of material that can survive frit glass cure temperatures in the 400-450° C. range is silver glass. If a solder or epoxy is used as used as the conductive material 4, then the reinforcement material can be an epoxy that is cured by UV or heat. Such epoxy-based reinforcements can be used for longer wavelength (i.e., non-UV) applications.

Once cured, the reinforcements 11a, 11b can improve reliability, increase vibration resistance, and, in the case of frit glass, improve heat dissipation. Alternatively, the entire LED die 6 can be reinforced by coating or encasing it within a layer of glass. Coating or encasing the LED die 6 can be achieved by stencil, nozzle or spray followed by sintering, as described in US Patent Application Publication No. 2010/0155764, for example.

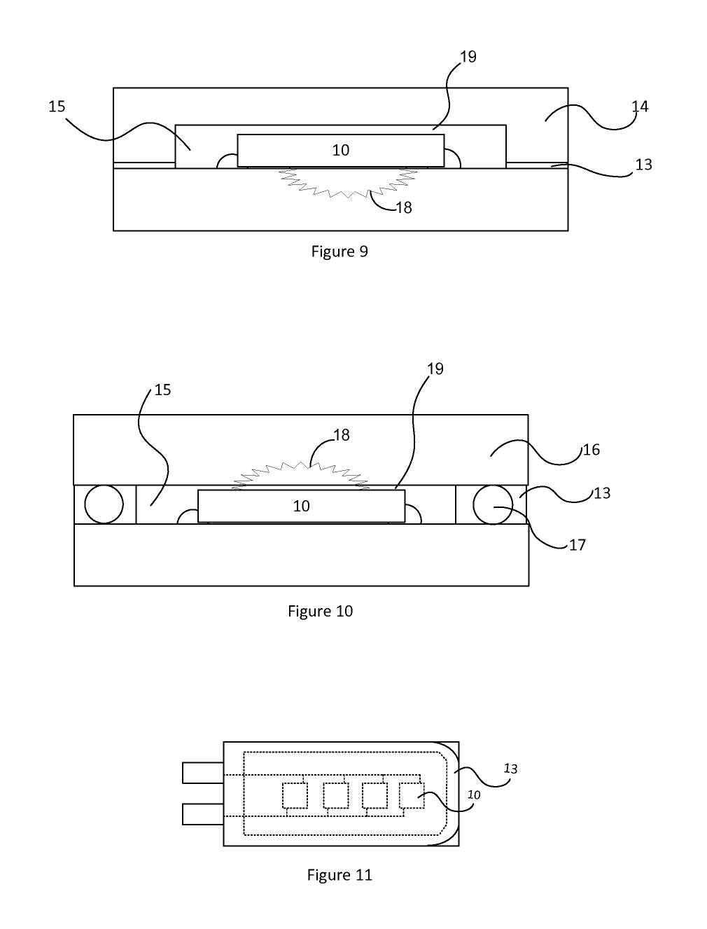

At step 1706, a hermetic seal is formed over the substrate 3 to enclose the LED die 6. In some embodiments, this is achieved by enclosing the LED die 6 in a conformal encapsulant by dispensing an encapsulating material over the LED die 6 and substrate. Depending on the orientation of the LED die 6 (and hence the direction of light emission), the encapsulant may or may not be transparent at the desired wavelengths and/or at optical wavelengths. However, in the embodiments described further below, the hermetic seal is formed by dispensing, screen-printing, or stencilling a continuous bead of sealing glass 13 along the periphery of the glass of either the glass substrate 3, as shown in FIG. 8, or of a glass lid that completes the enclosure. The lids can either be a lipped glass lid 14 as shown in the cross-sectional side view of FIG. 9, or a flat glass lid 16 with the same lateral dimensions as the substrate 3 as shown in FIG. 10. The glass lids 14, 16 can be received with the seal glass pre-dispensed thereon, and the seal glass 13 may be a glass of the same composition as the substrate 3 for light transmission therethrough. If a lipped glass lid 14 is used, it is aligned with the edges of the substrate 3, and sintered to fuse the glass at the periphery, as shown in FIG. 9. The sealing can be achieved by placing the entire assembly inside an oven at peak temperatures of 380-440° C. to melt the glass, thereby creating a hermetic seal. Heat causes the frit glass to reflow. Nitrogen or inert gases can be pumped into the oven to be trapped inside the inner volume 15 of the enclosure to minimize oxidation and degradation of the light source assembly. Alternatively, the sealing can be done in a vacuum oven to create a vacuum inside the enclosure. For robustness, the thicknesses of the glass substrate 3 and the glass lid 14, 16 is typically about ten-fold greater than the depth of the recesses 1 and wells 2 created in the substrate 3. A typical example is 1 mm minimum glass thickness for laser ablated recesses 1 and wells 2 of 75 micrometers in depth.

In the case of the unlipped glass lid or glass plate 16 shown in FIG. 10, spacers 17 are placed with the glass frit 13 to ensure that the lid 16 is spaced from the LED die 10. The spacers 13 can be glass balls with diameters that are at least as large as the height of the LED die 10. However, in alternative embodiments, the lids 14, 16 can be flush with the back side of LED die 10 by appropriate selection of the dimension the lip of the lid 14 or the spacers 13, and by controlling the bond height of the seal glass 13.

The result of the above process is a light source assembly in which at least one semiconductor LED die 10 is hermetically sealed with an enclosure. Electrical connections external to the enclosure are connected to electrical contacts on the LED die 10 so that the LED die 10 can be energised and made to emit light, whether in the visible range or otherwise. The LED die 10 is attached to an inner surface of one wall of the enclosure, and the electrical connections to the LED die 10 are formed on or integrally with that wall. The LED die 10 can be configured to emit light 18 from its bottom surface (i.e., the surface facing or abutting the enclosure wall on which the LED die 10 is mounted), as shown schematically in FIG. 9, or from its top surface (i.e., the surface facing away from the enclosure wall on which it is mounted), as shown schematically in FIG. 10, or both. As described above, the lid 14, 16 may or may not have a gap 19 between the lid 14, 16 and either or both of the emitting and non-emitting opposed surfaces of the LED die 10. The light source assemblies described herein are particularly suitable for use in high temperature and/or high UV radiation environments, but are also suitable for many other applications, including general lighting. Table 1 below lists some of the properties of typical materials used in the described embodiments, although other materials may be used in other embodiments.

Prior art glass light bulbs containing LED dies use tin alloy solder as the interconnect medium, which is not suitable for high temperature use and even at lower temperatures is usually the first point of failure. Furthermore, such bulbs require additional internal components, including wiring, a submount, lens, lead frame and heat sink. Such bulbs also use polymeric encapsulants that degrade when exposed to heat and/or UV light.

Although the enclosure in the described embodiments is entirely transparent (in this case to both the emitted UV light and to visible light), this is not necessary in general. For example, in the embodiments of FIG. 9, the lid 14 could be opaque to the emitted UV light because nearly all of the UV light is emitted through the UV transparent substrate 3. Similarly, the substrate 3 in the general arrangement shown in FIG. 10 could be opaque to the light emitted by the LED die 10 if the die 10 is mounted to emit light through the lid 14, 16 rather than through the substrate 3.

TABLE 1

| | | | | Melting | Thermal |
|---|---|---|---|---|---|
| | | Thermal | Volume | (Reflowing) | Expansion |
| | | conductivity | resistivity | Point | Coefficient |
| Material | Function | W/m C | μΩ-cm | ° C. | ppm/° C. |
| Silicon | LED | 149 | 230000 | 1410 | 4.2 |
| Sapphire | LED | 35 | 10²⁰ | 2050 | 5.0-6.6 |
| AlN | LED | 285 | insulator | 2200 | 4.15-5.27 |
| Aluminium | Interconnect | 240 | 4.3 | 660 | 23 |
| Au bump | Interconnect | 297 | 2.2 | 1063 | 14.2 |
| 80Au20Sn | Interconnect | 57 | 16 | 280 | 16 |
| 95Pb5Sn | Interconnect | 63 | 19 | 310 | 29 |
| Silver glass, | Interconnect/ | 79 | <15 | Reflows at | 14-16 |
| Henkel Hysol | conductor | | | 410 | |
| QMI2419 | | | | | |
| Silver epoxy | Interconnect/ | 2.4 | 200 | Cures at | 55 |
| Henkel Ablebond | conductor | | | 150 | |
| 84-1LMI | | | | | |
| UV transparent | Substrate/ | 1 | 10¹³-10¹⁷ | Reflows at | 4.1 |
| glass | lens/bulb/ | | | 410-430 | |
| Schott Glass 8337B | encasement | | | | |
| UV transparent | Substrate/ | 1 | 10¹³-10¹⁷ | Reflows at | 9.7 |
| glass | lens/bulb/ | | | 460-1000 | |
| Schott Glass 8405 | encasement | | | | |
| Sealing glass | Hermetic | 1 | 10¹³-10¹⁷ | Reflows at | 11.7 |
| Schott G017-052 | Sealing | | | 410 | |
| Sealing glass | Hermetic | 1 | 10¹³-10¹⁷ | Reflows at | 8.2 |
| Schott 8465 | Sealing | | | 460 | |

In white light applications, a yellow glass enclosure (or substrate only or lid only, as the case may be) can be selected to reduce blue light emission from the light source assembly. Similarly, pre-tinted glass with non-degradable colours can be used for some lighting applications. Additionally, the inner surface of the enclosure through which the light is predominantly emitted can be coated with a layer of phosphor and/or diffusing material to modify the wavelengths and/or directionality of light emission. In embodiments where there is a gap 19 between the light emitting surface of the LED die 10 and the lid 14, 16, this gap 19 can be filled with a fluid or gel to assist with cooling the LED dies 10 and/or to modify the light emission from the light source assembly. The fluid or gel may contain phosphor and/or diffusing particles to modify the wavelengths and/or directionality of light emission.

In some alternative embodiments (not shown), the substrate 3 includes an opening or through-hole therethrough and dimensioned to receive the LED die 10 such that the die itself closes the opening and a hermetic seal is then formed at the edges of the LED die 10. In some embodiments, the opening includes a peripheral lip or stop or flange that supports the LED die 10 by its edges. In these embodiments, the substrate material (e.g., sapphire) itself provides environmental protection, and the absence of the substrate 3 covering the light emitting surface of the LED die 10 reduces or avoids optical absorption in the substrate 3.

The light source assemblies described above include only one LED die 10 disposed within the hermetically sealed enclosure, with a single pair of terminals 7 protruding from the enclosure to provide electrical power to the LED die 10. However, other embodiments include multiple LED dies 10 enclosed within the one hermetically sealed enclosure, which can provide a higher packing density, higher illumination intensity, and substantial cost savings compared to the use of an equivalent number of individually packaged LED dies 10. In some embodiments with multiple LED dies, additional terminals protrude from the enclosure to allow at least some of the multiple LED dies 10 to be controlled independently. Thus, for example, a light source assembly of this type can be operated with only a subset (one or more) of the enclosed LED dies energised at a time. When one or more the energised LEDs fail, one or more of the other LED dies can be energised to replace the failed LED dies. This can be used to extend the effective lifetime of the light source assembly and thereby reduce the frequency of manual replacements (and hence downtime events).

It will be apparent to those skilled in the art that the light source assemblies described herein constitute particular forms of packaged LED(s), and that the described processes for producing the light source assemblies constitute LED packaging processes.

In some embodiments, the LED dies 10 are arranged as a linear or one-dimensional array, as shown in FIG. 11. This light source assembly has the general planar elongate shape of a paddle, planar wand, or flat panel, and, where the LED dies 10 are selected to predominantly emit UV radiation, has particular application to fluid sterilisation, where the light source assembly is immersed in the fluid to be sterilised, which flows along or around the light source assembly. Additionally, the relatively thin enclosure in the primary direction of UV emission allows it to be located very close to the object(s) to be irradiated, such as glues to be cured or food to be sterilised, thereby increasing the intensity of UV radiation at the object(s). Consequently, the UV light source assemblies described herein can be used in place of mercury vapour lamps.

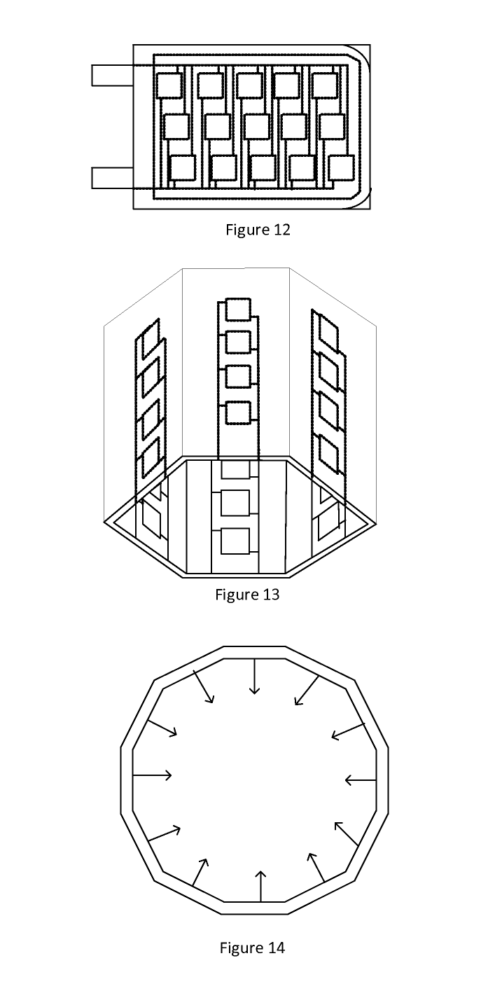

In some embodiments, the LED dies 10 are arranged as a two-dimensional array, as shown in FIG. 12, to provide a relatively large light-emitting planar surface area. Such relatively large area planar light source assemblies with UV-emitting LED dies are particularly useful for curing sheets of UV sensitive epoxy adhesives or tapes in many industries, or for sterilizing foods moving continuously on a conveyor belt, for example.

In some embodiments, a plurality of planar light source assemblies as described above are arranged generally circumferentially about a light receiving region. The light source assemblies can be oriented so that the emitted light is predominantly directed radially inwards to that region, and/or reflectors or mirrors can be used to (further) direct light radially inwards. For example, FIG. 13 shows an example where multiple (six in this example) elongate planar paddle-shaped light source assemblies are arranged generally circumferentially about a generally cylindrical light receiving region, with the light source assemblies forming a polygon (in this case a hexagon) when viewed from either end of the cylinder.

The circularity and dimensions of this general arrangement increase with increasing number of light source assemblies, as illustrated by the arrangement of twelve light source assemblies shown in end view in FIG. 14. In general, any practical number of assemblies greater than two can be used.

In embodiments where a curved substrate/enclosure is used, the LED dies 10 can be arranged as one- and two-dimensional arrays on one or more curved inner surfaces of the enclosure, thereby enabling arrangements with circular or elliptical cross-sections.

Such polygonal arrangements with light directed inwards to a light receiving region are particularly useful for sterilizing liquids flowing through the light receiving region. For example, the light source assemblies can be affixed to the walls of a channel or pipe through which the liquid or fluid is flowing, such as in water purification facilities, for example. The number of light source assemblies and their length can be selected to ensure complete sterilization for a given fluid, channel diameter, and flow rate. In some applications, a fluid or food to be sterilised is not flowing but is contained in glass bottles that are inserted into or moved through the light receiving region to sterilize the contents prior to bottle sealing.

For added safety, the enclosure can be made of relatively thick and tempered glass with relatively high hardness. In embodiments where such glass is in direct contact with the die, this also enhances cooling of the LED die(s) 10 within the enclosure. With the selection of only inorganic materials inside the bulb, the light source assemblies described herein do not degrade substantially in strong UV radiation. This relative stability under high intensity and/or prolonged UV radiation exposure improves the lifetime of the light source assemblies described herein and thus reduces their frequency of replacement.

Finally, one or more additional devices or circuits that are not LED dies can be included within the hermetically sealed enclosure. In some embodiments, these additional devices or circuitry include control circuitry that controls the supply of electrical power to the LED dies. In some embodiments, this control circuitry is operative to cause the intensity of UV light emission from the LED dies to pulse, which is more effective as a germicide than continuous UV light. In some embodiments, control circuitry is configured to increase the power supplied to the LED dies as they age to maintain a substantially constant emission intensity over time. It also will be apparent that such circuitry could be integrated with one or more LEDs on the same die or chip.

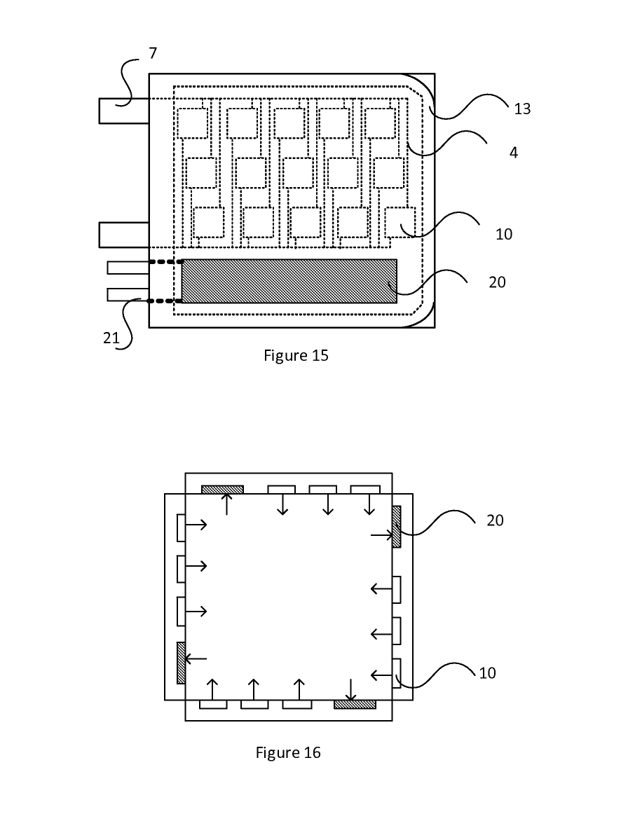

In some embodiments, these additional devices include sensors. The sensors can be any type of sensor that can be practically packaged with the LED die(s) within the same enclosure, such as temperature and optical sensors. For example, FIG. 15 is a schematic plan view of a light source assembly in which a two-dimensional array of LED dies 10 and an elongate sensor 20 are mounted to the same planar internal wall of the enclosure. In some embodiments, the sensor 20 is a photo detector that is used to monitor and thus control light intensity. As with the LED dies 10, the electrical connections to the sensor 20 are made in the same manner as those for the LED dies 10, as generally described above, and additional contact pins 21 extend from the enclosure. Such light source assemblies with optical sensors 20 can be particularly useful when two or more such light source assemblies are arranged to face one another, such as shown in FIG. 16, for example. In this arrangement, the sensor 20 of one assembly can be used to control the power supplied to the LED die(s) 10 of one or more of the other assemblies.

Many modifications will be apparent to those skilled in the art without departing from the scope of the present invention.

1. A light source assembly, including one or more light emitting diodes disposed within a hermetically sealed enclosure, wherein the light emitting diodes are in the form of one or more unpackaged planar semiconductor dies mounted on an inner surface of a wall of the enclosure, wherein the wall of the enclosure includes electrically conductive tracks that connect electrical contacts of the unpackaged planar semiconductor dies to corresponding electrical contacts external of the sealed enclosure.

2. The light source assembly of claim 1, wherein the electrically conductive tracks are disposed within corresponding recesses in the wall of the enclosure.

3. The light source assembly of claim 1, wherein the electrically conductive tracks are formed from a conductive paste.

4. The light source assembly of claim 1, wherein the electrical contacts of each unpackaged planar semiconductor die include bumps, and the recesses in the wall of the enclosure include bump recesses in which the bumps of the unpackaged planar semiconductor dies are disposed and which act to locate the unpackaged planar semiconductor dies.

5. The light source assembly of claim 1, wherein the inner surface of the wall of the enclosure is planar, and each unpackaged planar semiconductor die is mounted substantially flush against the inner planar surface of the wall of the enclosure.

6. The light source assembly of claim 1, wherein each unpackaged planar semiconductor die is configured to selectively emit UV radiation.

7. The light source assembly of claim 1, wherein the one or more unpackaged planar semiconductor dies are a plurality of unpackaged planar semiconductor dies.

8. The light source assembly of claim 7, wherein the plurality of unpackaged planar semiconductor dies are arranged as a one-dimensional array.

9. The light source assembly of claim 7, wherein the plurality of unpackaged planar semiconductor dies are arranged as a two-dimensional array.

10. The light source assembly of claim 1, including one or more sensors mounted within the sealed enclosure.

11. The light source assembly of claim 10, wherein the one or more sensors include one or more photodetectors to monitor the intensity of light emitted by the light emitting diodes.

12. The light source assembly of claim 1, wherein the wall of the enclosure is optically transparent.

13. The light source assembly of claim 12, wherein the wall is one of a plurality of optically transparent walls of the enclosure.

14. The light source assembly of claim 1, wherein each unpackaged planar semiconductor die is mounted to the inner surface of the wall of the enclosure in a flip chip configuration.

15. The light source assembly of claim 1, wherein the light source assembly is substantially in the form of a flat panel.

16. The light source assembly of claim 1, wherein the one or more light emitting diodes are a plurality of light emitting diodes, and the electrical contacts external of the sealed enclosure allow at least one of the light emitting diodes to be controlled independently of at least one other one of the light emitting diodes.

17. The light source assembly of claim 1, wherein each of the one or more unpackaged planar semiconductor dies has a light emitting planar surface spaced from a corresponding inner surface of the hermetically sealed enclosure and defining a gap therebetween, and the light source assembly includes a fluid or gel in the gap to assist with cooling the unpackaged planar semiconductor dies and/or to modify the light emission from the light source assembly.

18. The light source assembly of claim 17, wherein the fluid or gel includes phosphor and/or diffusing particles to modify the wavelengths and/or directionality of light emission.

19. A light source assembly, including a plurality of the light source assemblies of claim 1, the light source assemblies being arranged circumferentially about a region and directed radially inwards to said region.

20. A light source assembly, including one or more light emitting diodes disposed within a hermetically sealed enclosure, wherein the light emitting diodes are in the form of one or more unpackaged planar semiconductor dies mounted in respective openings in a wall of the enclosure such that the enclosure is formed in part by the unpackaged planar semiconductor dies, and wherein the wall of the enclosure includes electrically conductive tracks that connect electrical contacts of the unpackaged planar semiconductor dies to corresponding electrical contacts external of the sealed enclosure.

21. A process for producing a light source assembly, including:
forming electrically conductive tracks on a substrate;
mounting one or more light emitting diodes in the form of one or more unpackaged planar semiconductor dies to the substrate such that the electrically conductive tracks are electrically connected to electrical contacts of each unpackaged planar semiconductor die; and
hermetically sealing the unpackaged planar semiconductor dies within an enclosure formed in part by the substrate.

22. The process of claim 21, wherein the substrate is an optically transparent substrate.

23. The process of claim 21, wherein said mounting includes flip-chip mounting the unpackaged planar semiconductor dies to the substrate.

24. The process of claim 21, wherein said mounting includes mounting the unpackaged planar semiconductor dies in respective openings in the substrate such that the enclosure is formed in part by the unpackaged planar semiconductor dies.
